(19) United States
(12) Patent Application Publication
(10) Pub. No.: US 2023/0088313 A1
(43) Pub. Date: Mar. 23, 2023

(54) SYSTEM AND APPARATUS FOR GAS DISTRIBUTION

(71) Applicant: ASM IP Holding, B.V., Almere (NL)

(72) Inventors: Herbert Terhorst, Amersfoort (NL); Dinkar Nandwana, Chandler, AZ (US); Eric Shero, Phoenix, AZ (US); Allen D'Ambra, Phoenix, AZ (US); Jessica Akemi Cimada da Silva, Chandler, AZ (US); Daner Abdula, Phoenix, AZ (US)

(21) Appl. No.: 17/948,674

(22) Filed: Sep. 20, 2022

Related U.S. Application Data
(60) Provisional application No. 63/247,756, filed on Sep. 23, 2021.

(51) Int. Cl. B05B 1/00; B05B 1/18

(52) U.S. Cl. CPC B05B 1/005; B05B 1/185

(57) ABSTRACT

A gas distribution system having a first plurality of apertures to supply a gas source to a reaction chamber and a second plurality of apertures surrounding the first plurality of apertures and configured to remove the gas from the reaction chamber. In one embodiment, the second plurality of apertures may gradually increase in diameter as the distance from a main exhaust channel increases. Alternatively, or in addition, the angle spacing between adjacent apertures may gradually decrease as the distance from the main exhaust channel increases.

### CROSS-REFERENCE TO RELATED APPLICATIONS

This application is a nonprovisional of, and claims priority to and the benefit of, U.S. Provisional Patent Application No. 63/247,756, filed Sep. 23, 2021 and entitled, “SHOWERHEAD,” which is hereby incorporated by reference herein.

### FIELD OF INVENTION

The present disclosure generally relates to a gas distribution system and apparatus. More particularly, the present disclosure relates to a gas distribution system used during the fabrication of semiconductor devices.

### BACKGROUND OF THE TECHNOLOGY

During the semiconductor manufacturing process, a source gas is typically flowed into a reaction chamber via gas delivery holes located above a substrate (e.g., a wafer). During and/or after the source gas is flowed, a vacuum is activated to remove gas or other byproducts from the reaction chamber via an exhaust port. However, the exhaust port is typically located at one position within the reaction chamber, which creates an uneven or biased exhaust flow. This uneven exhaust flow pattern may negatively impact deposition uniformity, which may result in poor electrical characteristics of the wafer.

### SUMMARY OF THE INVENTION

Embodiments of the present technology may provide a gas distribution system having a first plurality of apertures to supply a gas source to a reaction chamber and a second plurality of apertures surrounding the first plurality of apertures and configured to remove the gas from the reaction chamber. In one embodiment, the second plurality of apertures may gradually increase in diameter as the distance from a main exhaust channel increases. Alternatively, or in addition, the angle spacing between adjacent apertures may gradually decrease as the distance from the main exhaust channel increases.

In one embodiment, a gas distribution plate, comprises: a first plurality of apertures configured to supply a source gas, wherein each aperture from the first plurality of apertures have a same diameter; and a second plurality of apertures surrounding the first plurality of apertures and configured to exhaust the source gas, wherein the second plurality of apertures comprises: a first subset of apertures having a first diameter; and a second subset of apertures having a second diameter that is larger than the first diameter.

In another embodiment, a gas distribution system, comprises: a gas distribution plate comprising a first plurality of apertures configured to supply a source gas, wherein the first plurality of apertures have a first diameter; and a second plurality of apertures surrounding the first plurality of apertures and configured to exhaust the source gas, wherein the second plurality of apertures have a second diameter and comprise: a first subset of apertures having a first spacing between adjacent apertures; and a second subset of apertures having a second spacing between adjacent apertures, wherein the second spacing is less than the first spacing.

In yet another embodiment, a gas distribution system comprises: a gas distribution plate comprising: a first plurality of apertures configured to supply a source gas, wherein each aperture from the first plurality of apertures have a same diameter; a second plurality of apertures arranged in a circular pattern along an outer edge of the gas distribution plate and surrounding the first plurality of apertures, and configured to exhaust the source gas, wherein the second plurality of apertures comprises: a first subset of apertures having a first diameter; and a second subset of apertures having a second diameter that is larger than the first diameter; and a main exhaust port located adjacent to the first subset of apertures.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 representatively illustrates a cross-sectional view of a system in accordance with an embodiment of the present technology

FIG. 2 representatively illustrates a bottom view of a gas distribution plate in accordance with an embodiment of the present technology;

FIG. 3 representatively illustrates a bottom view of a gas distribution plate in accordance with an embodiment of the present technology;

FIG. 4 representatively illustrates a bottom view of a gas distribution plate in accordance with an alternative embodiment of the present technology; and

FIG. 5 representatively illustrates a bottom view of a gas distribution plate in accordance with an embodiment of the present technology; and

FIG. 6 representatively illustrates a top view of a system in accordance with embodiments of the present technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure.

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

The present disclosure generally relates to a gas distribution system used during the fabrication of semiconductor devices.

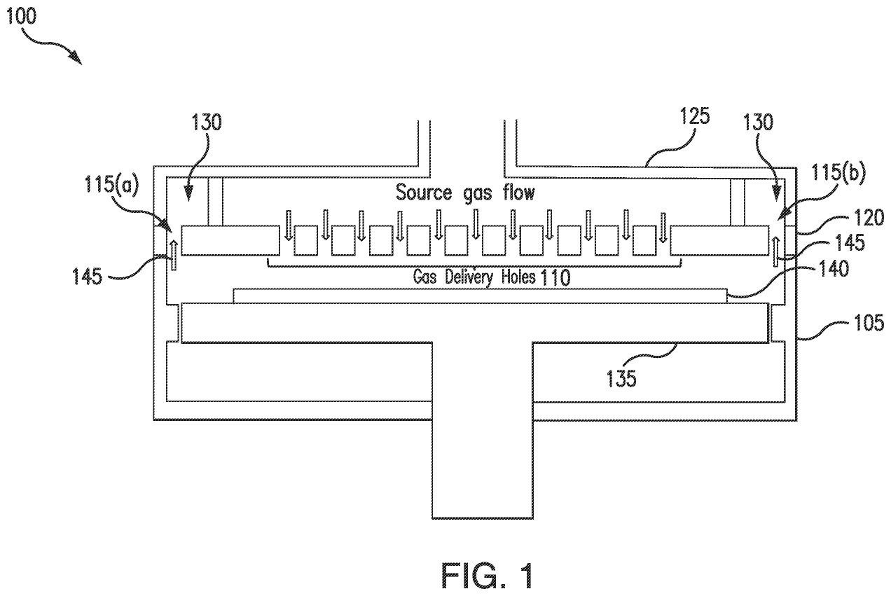

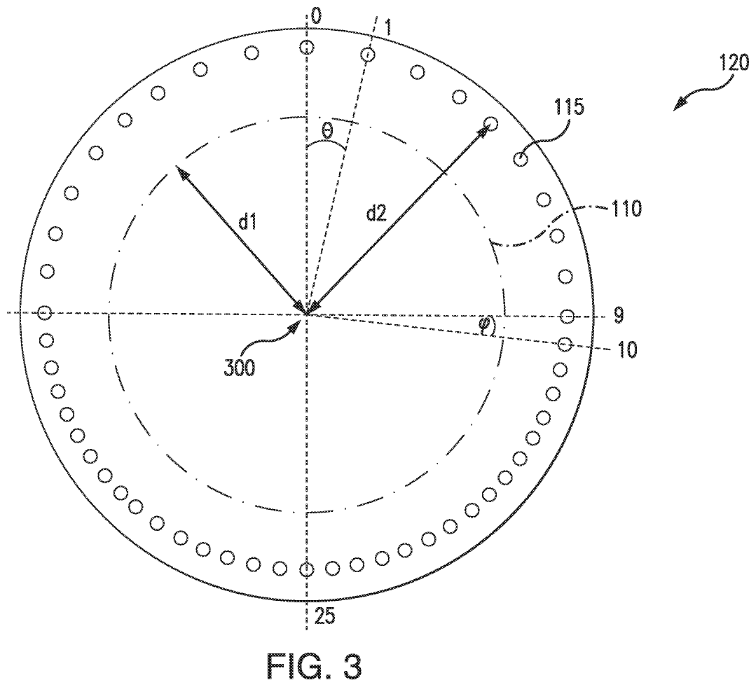

Referring to FIGS. 1 and 3, a system 100 may be configured for manufacturing semiconductor devices. In various embodiments, the system 100 may comprise a reaction chamber 105 and a gas distribution system 125. The system 100 may further comprise a susceptor 135 disposed within the reaction chamber 105. The susceptor 135 may comprise an upward-facing surface configured to support a substrate, such as a wafer 140. In various embodiments, the susceptor 135 may be heated.

In various embodiments, the gas distribution system 125 (i.e., a showerhead) may be positioned above the upward-facing surface of the susceptor 135. In various embodiments, the gas distribution system 125 may comprise a gas distribution plate 120. The gas distribution plate 120 may comprise a first plurality of apertures (i.e., holes) 110 and a second plurality of apertures (i.e., holes) 115.

In various embodiments, the first plurality of apertures 110 are arranged in a central area of the gas distribution plate 120 within a first distance d1 from a geometric center 300 (FIG. 3) of the gas distribution plate 120. The first plurality of apertures 110 may be arranged, generally, in a circular pattern. The first plurality of apertures 110 may be used to supply a source gas to the wafer 140 in the reaction chamber 105. The source gas may flow in a first direction that is a downward through the first plurality of apertures 110 toward the upward-facing surface of the susceptor 135 and/or wafer 140. The first plurality of apertures 110 may comprise any number of apertures suitable for the desired application, conductance/flow requirements, and the like. In addition, the apertures from the first plurality of apertures 110 may be arranged in rows or any other suitable pattern.

In various embodiments, the second plurality of apertures 115 may be arranged near an outer edge of the gas distribution plate 120 and surrounding the first plurality of apertures 110. In various embodiments, the second plurality of apertures 115 may be arranged in a single row and in a circular pattern. In various embodiments, all the apertures from the second plurality of apertures 115 may be a second distance d2 from a center point (i.e., the geometric center 300) of the gas distribution plate 120, where the second distance d2 is greater than the first distance d1.

The second plurality of apertures 115 may be used to exhaust or otherwise remove the gas from the reaction chamber 105. In various embodiments, exhaust flow is upwards and away from the upward-facing surface of the susceptor 135 and/or wafer 140. Accordingly, the flow of gas through the exhaust may be opposite that of the flow of the source gas. The second plurality of apertures 115 may comprise any number of apertures suitable for the desired application, conductance/flow requirements, and the like.

In various embodiments, the apertures from the second plurality of apertures 115 may have variable spacing. In other embodiments, the apertures from the second plurality of apertures 115 may have variable diameters. In yet other embodiments, both the diameter of the apertures 115 and the angle spacing between neighboring apertures 115 may vary. For example, the diameter of the aperture may increase while the angle spacing may decrease as the aperture number increases. For example, the angle spacing between apertures 0-9 may be larger than the angle spacing between apertures 15-20.

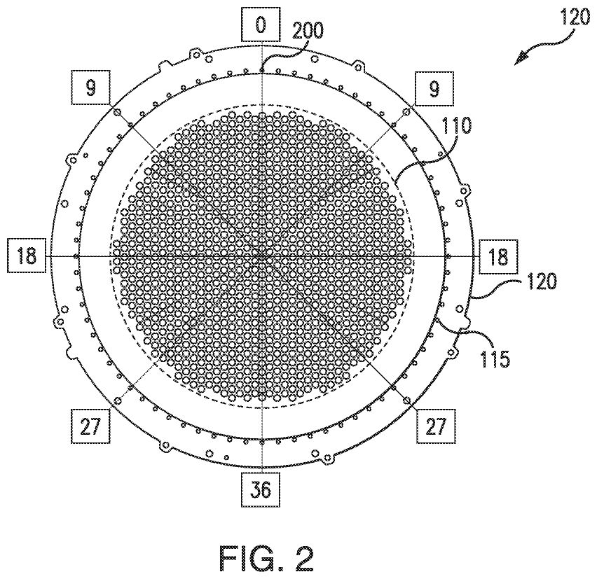

In various embodiments, and referring to FIGS. 2-5, the second plurality of apertures 115 may vary in size (i.e., diameter) and/or spacing (i.e., angle spacing). One aperture from the second plurality of apertures 115 may be identified as a reference aperture 200. All remaining apertures may be identified relative to the reference aperture 200. For example, the reference aperture 200 may be referred to as “aperture 0” and the remaining apertures may be referred to by an ascending sequential order number. For example, the aperture directly adjacent to aperture 0 may be referred to as aperture 1, the next directly adjacent aperture may be referred to as aperture 2, and so on.

In one embodiment, and referring to FIG. 3, each of the apertures from the second plurality of apertures 115 may have a same diameter, such as in a range of 3 mm to 5 mm. In the present embodiment, a first subset of adjacently-located (i.e., neighboring) apertures from the second plurality of apertures 115, may be separated by a first angle spacing θ. For example, aperture numbers 0 and 1 may be separated by the first angle spacing θ. Similarly, apertures 1 and 2, 2 and 3, 3 and 4, 4 and 5, 5 and 6, 6 and 7, 7 and 8, 8 and 9 may be separated by the first angle spacing θ. The first angle spacing θ may be in a range of 4.5 to 6 degrees.

In addition, a second subset of adjacently-located apertures from the second plurality of apertures 115, such as aperture numbers 9 and 10, may be separated by a second angle spacing φ. Similarly, 10 and 11, 11 and 12, 12 and 13, 13 and 14, 14 and 15, 15 and 16, 16 and 17, 17 and 18, 18 and 19, 19 and 20, 20 and 21, 21 and 22, 22 and 23, 23 and 24, 24 and 25 may be separated by the second angle spacing φ. Accordingly, in the present case, aperture numbers 0 to 9 have the same angle spacing θ and aperture numbers 9 to 25 have the same angle spacing φ. The second angle spacing φ may be in a range of 3 to 5 degrees. In various embodiments, the second angle spacing φmay be less than the first angle spacing θ.

Alternatively, and referring to FIG. 2 and Table 1 below, the angle spacing may gradually decrease as the aperture number increases. For example, as described below, the angle spacing may gradually decrease from aperture number 0 to aperture number 36.

TABLE 1

| | Angle | Diameter |
|---|---|---|
| Hole | Spacing | of Each Hole |
| Number | (in Degree) | (in mm) |
| 0 | NA | 5.00 |
| 1 | 5.83 | 5.00 |
| 2 | 5.85 | 5.00 |
| 3 | 5.85 | 5.00 |
| 4 | 5.84 | 5.00 |
| 5 | 5.80 | 5.00 |
| 6 | 5.75 | 5.00 |
| 7 | 5.68 | 5.00 |
| 8 | 5.60 | 5.00 |
| 9 | 5.53 | 5.00 |
| 10 | 5.46 | 5.00 |
| 11 | 5.40 | 5.00 |
| 12 | 5.34 | 5.00 |
| 13 | 5.28 | 5.00 |
| 14 | 5.22 | 5.00 |
| 15 | 5.17 | 5.00 |
| 16 | 5.00 | 5.00 |
| 17 | 4.84 | 5.00 |
| 18 | 4.80 | 5.00 |
| 19 | 4.76 | 5.00 |
| 20 | 4.72 | 5.00 |
| 21 | 4.69 | 5.00 |
| 22 | 4.65 | 5.00 |
| 23 | 4.62 | 5.00 |
| 24 | 4.60 | 5.00 |
| 25 | 4.57 | 5.00 |
| 26 | 4.55 | 5.00 |
| 27 | 4.53 | 5.00 |
| 28 | 4.50 | 5.00 |
| 29 | 4.49 | 5.00 |
| 30 | 4.47 | 5.00 |
| 31 | 4.46 | 5.00 |
| 32 | 4.45 | 5.00 |
| 33 | 4.44 | 5.00 |
| 34 | 4.43 | 5.00 |
| 35 | 4.43 | 5.00 |
| 36 | 4.39 | 5.00 |

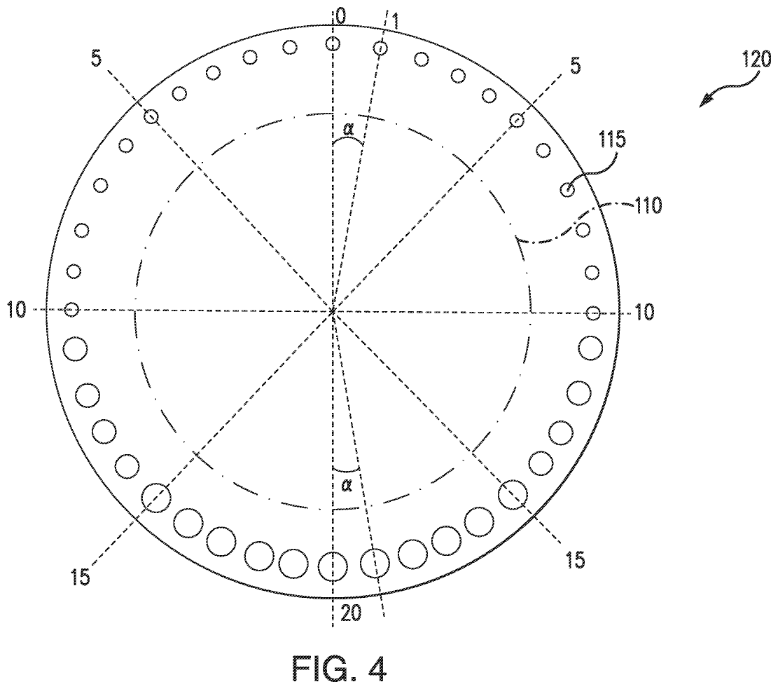

In various embodiments, the apertures from the second plurality of apertures 115 may have varying diameters, such as ranging from 3 mm to 6 mm. For example, and referring to FIG. 4, aperture numbers 0 to 10 may have a same first diameter and aperture numbers 11 to 20 have a same second diameter, wherein the second diameter is larger than the first diameter. In the present embodiment, all adjacently-located apertures may be separated by a third angle spacing α.

Alternatively, and referring to FIG. 2 and Table 2 below, the second plurality of apertures 115 may be separated by the same angle spacing while the diameters of the apertures 115 may gradually increase as the aperture number increases.

TABLE 2

| | Angle | Diameter |
|---|---|---|
| Hole | Spacing | of Each Hole |
| Number | (in Degree) | (in mm) |
| 0 | NA | 4.82 |
| 1 | 5.00 | 4.82 |
| 2 | 5.00 | 4.82 |
| 3 | 5.00 | 4.82 |
| 4 | 5.00 | 4.82 |
| 5 | 5.00 | 4.83 |
| 6 | 5.00 | 4.84 |
| 7 | 5.00 | 4.86 |
| 8 | 5.00 | 4.87 |
| 9 | 5.00 | 4.89 |
| 10 | 5.00 | 4.90 |
| 11 | 5.00 | 4.92 |
| 12 | 5.00 | 4.93 |
| 13 | 5.00 | 4.94 |
| 14 | 5.00 | 4.95 |
| 15 | 5.00 | 4.97 |
| 16 | 5.00 | 5.03 |
| 17 | 5.00 | 5.04 |
| 18 | 5.00 | 5.05 |
| 19 | 5.00 | 5.06 |
| 20 | 5.00 | 5.07 |
| 21 | 5.00 | 5.08 |
| 22 | 5.00 | 5.09 |
| 23 | 5.00 | 5.10 |
| 24 | 5.00 | 5.10 |
| 25 | 5.00 | 5.11 |
| 26 | 5.00 | 5.12 |
| 27 | 5.00 | 5.12 |
| 28 | 5.00 | 5.13 |
| 29 | 5.00 | 5.13 |
| 30 | 5.00 | 5.14 |
| 31 | 5.00 | 5.14 |
| 32 | 5.00 | 5.14 |
| 33 | 5.00 | 5.14 |
| 34 | 5.00 | 5.14 |
| 35 | 5.00 | 5.15 |
| 36 | 5.00 | 5.15 |

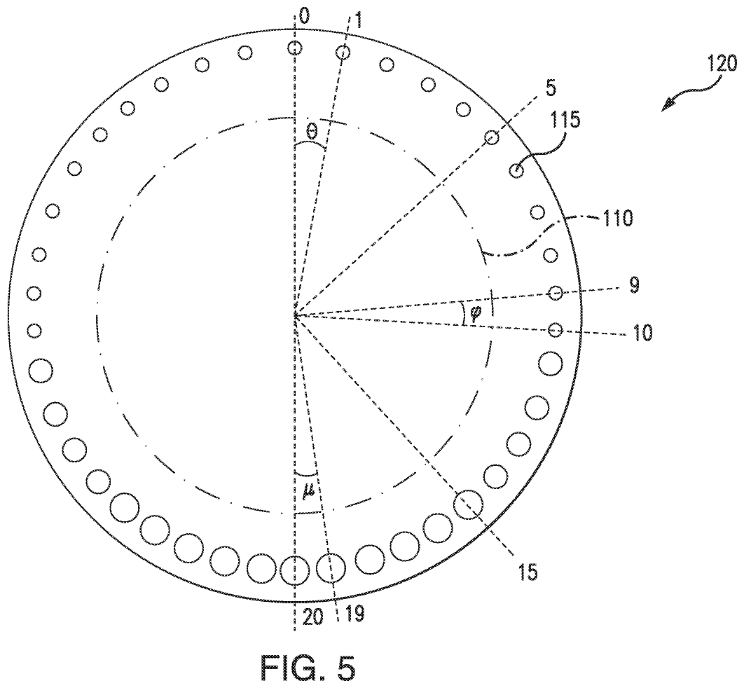

In various embodiments, and referring to FIG. 5, both the diameter of the apertures 115 and the angle spacing between neighboring apertures 115 may vary. For example, the diameter of the apertures 115 may increase while the angle spacing may decrease as the aperture number increases. In some cases, the diameter of the apertures 115 may increase gradually, such as described in Table 2, above. In other cases, the diameter of the apertures 115 may increase, but may be selected from finite number of diameters, such as 2, 3, 4, 5, or the like. For example, the first 3 apertures would have a same diameter, the next 3 apertures would have a same diameter, but larger than the diameter of the first 3 apertures, and so on.

In some cases, the angle spacing of the apertures 115 may decrease gradually, such as described in Table 1, above. In other cases, the angle spacing of the apertures 115 may decrease, but may be selected from a finite number of angle spacing, such as 2, 3, 4, or the like. For example, apertures 0-5 may have the first angle spacing θ between adjacent apertures 115, apertures 5-15 may have the second angle spacing φ, and apertures 15-20 may have a third angle spacing μ (where θ>φ>ν).

In various embodiments, the gas distribution system 125 may further comprise an exhaust channel 130. Each aperture from the second plurality of apertures 115 may be in communication with the exhaust channel 130. In other words, the exhaust channel 130 and the second plurality of apertures 115 are connected to allow gas to flow through the second plurality of apertures 115 and into the exhaust channel 130. In various embodiments, the exhaust channel 130 is accessed only though the second plurality of apertures 115.

In various embodiments, and referring to FIGS. 1 and 5, the system 100 may further comprise a main exhaust port 500 located at or near the reference aperture 200 (e.g., aperture number 0) to remove the exhaust gas from the system 100. The main exhaust port 500 may be connected to a pump (not shown), located downstream from the main exhaust 500, to facilitate removal of the exhaust gas. In various embodiments, the exhaust channel 130 is connected to the main exhaust port 500, such that exhaust gas from the exhaust channel 130 is able to flow out of the main exhaust port 500.

In various embodiments, the diameter of each aperture from the second plurality of apertures 115 may gradually increase as the distance from the main exhaust port 500 increases. In other words, the diameter of apertures from the second plurality of apertures 115 that are closer to the main exhaust port 500 may be smaller than those apertures that are further from and/or opposite the main exhaust port 500. For example, apertures 0-9 may have a smaller diameter than apertures 15-20.

In various embodiments, the angle spacing that separates adjacently-located apertures from the second plurality of apertures 115 may gradually decrease as the distance from the main exhaust port 500 increases. In other words, the angle spacing between apertures from the second plurality of apertures 115 that are closer to the main exhaust port 500 may be larger than the angle spacing between apertures that are further from and/or opposite the main exhaust port 500.

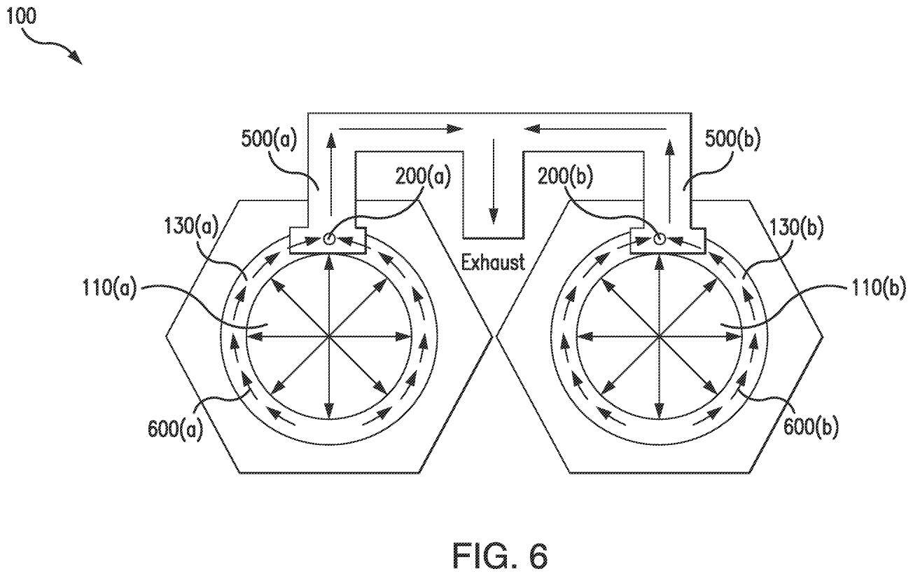

In operation, and referring to FIGS. 1 and 6, the source gas may be pulsed into the reaction chamber 105 via the first plurality of apertures 110 of the gas distribution plate 120. A purge gas may be then be pulsed into the reaction chamber 105 via the first plurality of apertures 110 of the gas distribution plate 120. During or between the pulsing of the source gas and/or the purge gas, the pump (not shown) may operate to facilitate removing the source gas and/or the purge gas from the reaction chamber 105 via the second plurality of apertures 115. The gas flows through the second plurality of apertures 115 and into the exhaust channel 130. Once in the exhaust channel 130, the gas flows along a flow path 600 towards the main exhaust port 500 and out of the system 100.

In various embodiments, and referring to FIG. 6, the system 100 may comprise multiple reaction chambers 105, such as a first reaction chamber with a respective gas distribution system 125 comprising the first plurality of apertures 110(a), exhaust gas channel 130(a), main exhaust port 500(a), reference aperture 200(a), and flow path 600(a), and a second reaction chamber with a respective gas distribution system 125 comprising the first plurality of apertures 110(b), exhaust gas channel 130(b), main exhaust port 500(b), reference aperture 200(b), and flow path 600(b). In the present case, the main exhaust ports 500(a), 500(b) may be connected or otherwise merge into a single exhaust path.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

1. A gas distribution plate, comprising:
a first plurality of apertures configured to supply a source gas, wherein each aperture from the first plurality of apertures have a same diameter; and
a second plurality of apertures surrounding the first plurality of apertures and configured to exhaust the source gas, wherein the second plurality of apertures comprises:
a first subset of apertures having a first diameter; and
a second subset of apertures having a second diameter that is larger than the first diameter.

2. The gas distribution plate according to claim 1, further comprising a main exhaust port located adjacent to a first aperture from the second plurality of apertures.

3. The gas distribution plate according to claim 2, wherein the first subset of apertures are located closer to the main exhaust than the second subset of apertures.

4. The gas distribution plate according to claim 1, wherein the second plurality of apertures are arranged along an outer edge of the gas distribution plate.

5. The gas distribution plate according to claim 1, wherein the second plurality of apertures are spaced equidistant from each other.

6. The gas distribution plate according to claim 1, wherein the second plurality of apertures have variable spacing from each other.

7. The gas distribution plate according to claim 6, wherein the spacing between two neighboring apertures from the first subset of apertures is greater than the spacing between two neighboring apertures from the second subset of apertures.

8. The gas distribution plate according to claim 1, wherein the second plurality of apertures are arranged in a circular pattern.

9. The gas distribution plate according to claim 1, wherein the first plurality of apertures are arranged within a central region of the gas distribution plate.

10. A gas distribution system, comprising:
a gas distribution plate, comprising:
a first plurality of apertures configured to supply a source gas, wherein the first plurality of apertures have a first diameter; and
a second plurality of apertures surrounding the first plurality of apertures and configured to exhaust the source gas, wherein the second plurality of apertures have a second diameter and comprise:
a first subset of apertures having a first spacing between adjacent apertures; and
a second subset of apertures having a second spacing between adjacent apertures, wherein the second spacing is less than the first spacing.

11. The gas distribution system according to claim 10, wherein the first plurality of apertures are arranged within a central region of the gas distribution plate and the second plurality of apertures are arranged along an outer edge of the gas distribution plate.

12. The gas distribution system according to claim 10, wherein the second plurality of apertures are arranged in a circular pattern.

13. The gas distribution system according to claim 10, wherein the first subset of apertures have a first diameter and the second subset of apertures have a second diameter that is larger than the first diameter.

14. The gas distribution system according to claim 10, wherein each of the first subset of apertures and the second subset of apertures have a same diameter.

15. The gas distribution system according to claim 10, further comprising a main exhaust port located adjacent to a first aperture from the second plurality of apertures.

16. The gas distribution system according to claim 10, wherein the first set of apertures are located closer to the main exhaust than the second set of apertures.

17. A gas distribution system, comprising:
a gas distribution plate, comprising:
a first plurality of apertures configured to supply a source gas, wherein each aperture from the first plurality of apertures have a same diameter;
a second plurality of apertures arranged in a circular pattern along an outer edge of the gas distribution plate and surrounding the first plurality of apertures, and configured to exhaust the source gas, wherein the second plurality of apertures comprises:
a first subset of apertures having a first diameter; and
a second subset of apertures having a second diameter that is larger than the first diameter; and
a main exhaust port located adjacent to the first subset of apertures.

18. The gas distribution system according to claim 17, wherein each of the second plurality of apertures connects to a single exhaust channel that extends along the outer edge of the gas distribution plate, wherein the exhaust line is adjacent to the second plurality of apertures.

19. The gas distribution system according to claim 18, wherein the exhaust channel connects to the main exhaust port.

20. The gas distribution system according to claim 17, wherein adjacent apertures from the first subset of apertures are separated by a first spacing and adjacent apertures from the second subset of apertures are separated by a second spacing, wherein the second spacing is less than the first spacing.
